(19) United States
(12) Patent Application Publication
(10) Pub. No.: US 2025/0185190 A1
(43) Pub. Date: Jun. 5, 2025

(54) HOUSING CAP AND HOUSING FOR AN ELECTRONICS COMPONENT

(71) Applicant: SCHOTT AG, Mainz (DE)

(72) Inventors: Christoph KIESL, Landshut (DE); Rainer GRAF, Kumhausen (DE); Robert HETTLER, Kumhausen (DE)

(73) Assignee: SCHOTT AG, Mainz (DE)

(21) Appl. No.: 18/846,039

(22) PCT Filed: Feb. 6, 2023
(86) PCT No.: PCT/EP2023/052807

§ 371 Date: Sep. 11, 2024

(30) Foreign Application Priority Data
Apr. 5, 2022 (DE) 10 2022 108 127.3

(51) Int. Cl. H05K 5/02; H05K 5/04; H05K 5/06

(52) U.S. Cl. CPC H05K 5/0217; H05K 5/04; H05K 5/069

(57) ABSTRACT

A housing cap for an electronics component includes a main body with an opening which is closed by a window. The window is connected to the main body using a compensation element, wherein there is an integral connection using a first connection material between the compensation element and the window and there is an integral connection using a second connection material between the compensation element and the main body, wherein a first coefficient of thermal expansion of the window is adapted to a second coefficient of thermal expansion of the compensation element or the first coefficient of thermal expansion is lower than the second coefficient of thermal expansion.

The invention relates to a housing cap for an electronic component, comprising a main body having an opening closed by a window. Further aspects of the invention relate to a housing comprising such a housing cap and to the use of the housing and the housing cap.

### PRIOR ART

Electronic components such as light-emitting diodes (LEDs), LASERs or photodiodes are typically accommodated in a housing that protects the electronic component and has a window transparent to electromagnetic radiation having the wavelength utilized by the electronic component.

Such a housing is known, for example, from WO 2021 214040 A1. The housing has a housing cap having an opening closed by a transparent element, and a base plate connected to the housing cap. In one variant, the transparent element is held on the housing cap by means of a glass solder. In another variant, the transparent element is held on the housing cap by means of a metallic solder, preferably an AuSn solder.

A disadvantage of the prior art is that a glass solder must never be under tensile stress. As a result, bonding of the window to the housing cap using a glass solder is possible only when the coefficient of thermal expansion of the housing cap is greater than the coefficient of thermal expansion of the window, or the two coefficients of thermal expansion are the same. Depending on the optical demands on the window and the material demands for the housing cap, it is not always possible to meet this condition, and so it is necessary to resort to metal solders such as gold-tin solders with, for example, 80% gold and 20% tin. However, these solder materials are very costly and, furthermore, it is necessary in the case of preferred window materials such as sapphire to pretreat the surface of the window so that the metal solder can adhere to the window. Furthermore, in these arrangements, when a metal solder is used, the window material is put under tensile stress, and so the mechanical stability thereof is weakened.

It would thus be desirable, for example, to be able to bond a window made of sapphire to a housing cap without complex surface pretreatment and costly gold-containing metal solders. In addition, it would be desirable not to mechanically weaken the window via tensile stresses.

### DISCLOSURE OF THE INVENTION

A housing cap for an electronic component is proposed. The housing cap comprises a main body having an opening closed by a window. The window is joined to the main body using a compensation element, wherein there is a cohesive bond using a first bonding material between the compensation element and the window and there is a cohesive bond using a second bonding material between the compensation element and the main body, wherein a first coefficient of thermal expansion of the window is matched to a second coefficient of thermal expansion of the compensation element or the first coefficient of thermal expansion is less than the second coefficient of thermal expansion.

Preferably, in a first variant i), the second coefficient of thermal expansion of the compensation element is greater than a third coefficient of thermal expansion of the main body. Alternatively, in a second variant ii), the second coefficient of thermal expansion of the compensation element is less than the third coefficient of thermal expansion of the main body.

The figures given herein for the coefficients of thermal expansion are based here on a temperature range from 20° C. to 300° C.

The housing cap is set up to be joined to further parts to form a housing and to accommodate at least one electronic component. The electronic component is preferably an optoelectronic component that emits and/or receives electromagnetic radiation, for example visible light or infrared light. The window is selected here such that it is transparent to the electromagnetic radiation emitted or received by the electronic component. The housing cap may of course also be designed such that multiple electronic components can be accommodated in a housing formed. It may be the case here that multiple electronic components are assigned a single window, or that multiple windows are provided in the housing cap. Accordingly, the housing cap may have one or more openings that are closed by one or more windows. If the housing cap has two or more windows, each of these windows may be secured to the main body via a dedicated compensation element. But it is also conceivable here that, for example, two or more windows are secured to the main body using one compensation element.

The window is preferably bonded to the main body using the compensation element and the first and second bonding materials on the outside of the main body. Alternatively, the window may also be bonded to the main body using the compensation element on the inside of the main body. For the first cohesive bond between the window and the frame using the first bonding material, the second coefficient of thermal expansion of the compensation element is preferably matched to the first coefficient of thermal expansion of the window, wherein matching means a difference in the coefficients of thermal expansion of not more than 0.5 ppm, preferably of not more than 0.2 ppm/K and more preferably of not more than 0.1 ppm/K.

If this matching is impossible owing to the selection of materials for the window and the compensation element, the second coefficient of thermal expansion of the compensation element is chosen such that it is greater than the first coefficient of thermal expansion of the window. A difference between the second coefficient of thermal expansion and the first coefficient of thermal expansion is here preferably in the range of greater than 0 to 5 ppm/K, more preferably in the range of greater than 0 to 3 ppm/K greater, most preferably in the range of greater than 0 to 1 ppm/K. It may be the case that establishment of a difference between the first coefficient of thermal expansion of the window and the second coefficient of thermal expansion of the compensation element allows controlled transfer of compression forces to the window. In this way, the window may be pretensioned such that it is strengthened with respect to mechanical stresses. In this case, the difference is preferably at least 1 ppm/K, more preferably at least 2 ppm/K and most preferably at least 4 ppm/K.

This also achieves the effect that, after the establishment of the cohesive bond at a processing temperature, the first bonding material is always under a compressive stress exerted by the compensation element. In the case that the ambient temperature is increased to a temperature below the processing temperature, this compressive stress becomes smaller, but no tensile stresses are exerted on the first bonding material even in the case of temperature changes within a temperature range acceptable for the operation of the component. The acceptable temperature range specified for entertainment electronics may, for example, be in the range from 0° C. to 70° C., for applications in the industrial sector in the range from −40° C. to 85° C., in the automotive sector in the range from −40° C. to 125° C., and for military applications in the range from −55° C. to 125° C. In addition, for high-temperature applications in industry, the maximum temperature of the acceptable temperature range may be specified as 200° C.

Another case that can occur according to variant ii) is that the third coefficient of thermal expansion of the main body is very much greater than the first coefficient of thermal expansion of the window. In such cases, although no tensile stresses occur, the compressive stresses generated in the case of large differences between the third and the first coefficients of thermal expansion can become so great that the bonding materials used, especially glass solders, do not withstand the forces. Such situations can arise, for example, in the case of a difference of more than 5 ppm/K, especially more than 7.5 ppm/K. The provision of a compensation element with a second coefficient of thermal expansion having a value between that of the window and the main body can limit the difference in coefficients of thermal expansion that occur and hence the compressive forces that occur. In the case of large component dimensions, especially in the case of a diameter, or the longer edge length in the case of rectangular windows, of 20 mm or more, even a relatively small difference in the coefficients of thermal expansion may be considered to be large. In such cases, preference is given to the arrangement of the compensation element even over and above a difference of about 3 ppm/K.

The providing of the compensation element and of the two different cohesive bonds permits choosing of the material of the main body of the housing cap independently of the material and hence the coefficient of expansion of the window. In particular, for the main body, it is possible to use materials having a coefficient of thermal expansion less than the first coefficient of thermal expansion of the window. Such selections, in the case of a direct cohesive bond between the window and the housing cap, would exert tensile forces on the bonding material used, which means that glass solders in particular cannot be used. Preferably, the third coefficient of thermal expansion of the main body is chosen to be at least 0.2 ppm/K, more preferably at least 0.5 ppm/K, smaller than the first coefficient of thermal expansion of the window.

The first bonding material is preferably connected exclusively to the compensation element and the window, such that no transmission of forces, especially tensile forces, to the first bonding material is possible from other parts of the housing cap either, such as the main body.

The compensation element is preferably configured such that it takes the form of a frame. The frame shape is preferably designed here such that the shape of the frame follows the shape of the opening in the main body. The opening formed by the frame may be exactly as large as the opening of the main body here. The opening in the frame may however alternatively also be larger or smaller. The frame may be of a flat design and may take the form, for example, of a flat metal sheet having an opening therein. As an alternative to a flat shape, the frame may have elevations and/or depressions. Elevations may be obtained, for example, from an originally flat sheet metal part by bending. Elevated or depressed regions may also be obtained, for example, by machining.

A thickness of the compensation element is preferably chosen to be sufficiently great that it is not deformed under the forces that occur by virtue of the different coefficients of thermal expansion. At the same time, the thickness is preferably chosen to be as low as possible, in order that maximum compactness of design of the housing cap is achieved. The thickness of the compensation element is chosen, for example, within the range from 0.05 mm to 2 mm. The thickness of the compensation element is preferably chosen to be low, i.e. preferably thinner than 1 mm, more preferably thinner than 0.5 mm and more preferably thinner than 0.2 mm, in order to keep the dimensions of the housing as compact as possible. At the same time, the thickness of the compensation element is chosen to be sufficiently thick to enable attenuation of the difference in the coefficients of thermal expansion. By choosing a thickness of at least 0.1 mm, it is possible to further increase attenuation.

In the cohesive bonding of the frame to the window, the first bonding material is melted such that it becomes free-flowing and is bonded efficiently to the two joining partners. The frame is preferably set up to limit any flow of the first bonding material that occurs. For this purpose, the frame preferably has an elevated edge. The frame preferably adjoins an outer contour of the frame form and may be obtained, for example, by upward folding of a flat frame blank or by machining of the non-elevated parts of the frame. The elevated edge is preferably set up to limit the flow of the first bonding material. For this purpose, the elevated edge, in one variant, may have a fully circumferential configuration, or the elevated edge may be interrupted at vertices of the frame. Such interruptions in the elevated edge are advantageous especially when the corresponding vertices of the window are not beveled, but in sharp-edged form. If the vertices of the elevated edge on the compensation element are exposed by the interruptions, the window may remain sharp-edged, and no collision with any inner radii of the circumferential elevated edge occurs in the course of assembly.

The height of the elevated edge is preferably chosen such that it protrudes above the window. For example, the elevated edge protrudes above the window by a length in the range from 100 μm to 500 μm. In this execution variant, the elevated edge additionally assumes a protective function. The elevated edge in particular protects the edges of the window from mechanical damage. Alternatively, the elevated edge may however also be configured such that it concludes flush with the window or does not protrude above the window. In order to be able to limit flow of the first bonding material, the elevated edge preferably has a minimum height in the order of magnitude of the thickness of the layer of the first bonding material formed. For this purpose, for example, the minimum height is chosen within the range from 20 μm to 300 μm.

Preferably, the main body has a top wall and one or more side walls. The main body is preferably in one-piece form, such that, in particular, the top wall and the side walls are in one-piece form. The main body is preferably formed like a hat, in such a way that the side walls formed in one piece together with the top wall take the form of a laterally circumferential wall with four planar side walls in particular. A wall thickness of the top wall and/or of the side walls is preferably in the range from 0.1 to 1 mm. Main bodies with such wall thicknesses can be easily manufactured, for example, as a thermoformed part. In the case of production of the main body as a thermoformed part, the top wall and any flange present will typically have a greater wall thickness than the side walls. Main bodies having a constant wall thickness, where the side walls and the top wall in particular have the same wall thickness, may be obtained, for example, as a machined part.

The opening in the main body is preferably arranged in a side wall of the main body. The side wall may have protruding surfaces outside a region with the opening. These protruding surfaces may project beyond the window and hence provide particularly reliable protection of the window and of the compensation element from mechanical damage. In cases in which the protruding surfaces conclude flush with the window or do not project beyond the window, at least protection of the connection between the main body and the compensation element is provided. The protruding surfaces may be formed and arranged such that a depression is formed around the opening in the side wall, which can serve as positioning aid for the connection to the compensation element.

The side wall with the opening may run at right angles here in relation to an adjoining top wall, i.e. form an angle of about 90°. Alternatively, the side wall may run obliquely in relation to the adjoining top wall, i.e., for example, form an angle in the range from about 45° to 135°. It is also however conceivable that the side wall with the opening runs perpendicularly in relation to the top wall and runs obliquely in relation to an adjoining further side wall. Such an oblique arrangement can avoid troublesome back-reflections of electromagnetic radiation, for example of laser radiation into the electronic component that emits it.

The material of the window is preferably chosen in accordance with the demands on transparency to electromagnetic radiation. Further criteria for the selection of the material are in particular the hardness of the material. The window is preferably transparent to light having wavelengths in the range from 260 nm (UV) to 11 μm (infrared). The window is more preferably transparent to visible light and light in the near-infrared region, for example having a wavelength of about 1440 nm. Especially for infrared-based laser sensors such as LiDAR sensors, preference is given to windows that are transparent to infrared light having a wavelength of 800 nm to 2000 nm, for example laser radiation having a wavelength of 1440 nm. What is meant here by “transparent” is in particular that more than 50%, preferably more than 80% and more preferably more than 85% of the electromagnetic radiation passes through the window.

The material of the window is preferably sapphire, or the material for the window is selected from a glass, especially a borosilicate glass or an optical glass such as BK7, or a glass-ceramic. For applications that require transparency of the window in the infrared region, it is also possible, for example, to select silicon or germanium as window material.

The shape of the window preferably follows the shape of the opening in the main body of the housing cap, wherein the window is preferably chosen to be somewhat larger, in order to be able to bind to the edges thereof with the compensation element without covering parts of the opening in the main body.

The edge of the window may have a bevel in order to increase strength.

Typical dimensions for the opening in the main body and correspondingly for the window are in the range from 5 mm to 50 mm. In the case of a rectangular shape, optionally in combination with rounded edges, the height may, for example, be in the range from 5 mm to 20 mm, and the width, for example, in the range from 10 mm to 50 mm. Further preferred shapes for the opening especially include circular and elliptical shapes, preferably with a main axis running in a direction parallel to the plane of the top wall in the case of an elliptical shape.

The thickness of the window is preferably chosen to be as small as possible, in order to save material and build space. At the same time, however, the window should not go below a minimum thickness in order that it is sufficiently mechanically stable and cannot warp. If the window should deform, unwanted lens effects could occur. Accordingly, the thickness of the window is preferably chosen within the range from about 0.75 mm to 2.5 mm, more preferably in the range from 1 mm to 2 mm. When sapphire is chosen as window material, the thickness is, for example, 1 mm.

For avoidance of unwanted back-reflections and for improvement of transmittance, the window may have been provided, for example, with an antireflection coating. But it is also possible to use other types of coatings that, for example, are transparent only to particular wavelengths, such as a bandpass filter.

The material of the main body of the housing cap is preferably selected such that the housing cap has good mechanical stability and good joinability to other housing parts to form a housing. The material of the main body is preferably selected from a metal, especially an iron-nickel-cobalt alloy such as Kovar®, a stainless steel, aluminum or molybdenum.

In the case of materials of the main body having a low coefficient of thermal expansion, especially a coefficient of thermal expansion of less than 6 ppm/K, it is generally the case that case i) occurs, in which the second coefficient of thermal expansion of the compensation element is chosen to be greater than the third coefficient of thermal expansion of the main body. This is the case, for example, for molybdenum or an iron-nickel-cobalt alloy such as Kovar® as material for the main body. In the case of materials of the main body with a high coefficient of thermal expansion, especially a coefficient of thermal expansion above 10 ppm/K, case ii) generally occurs, in which the second coefficient of thermal expansion of the compensation element is chosen to be smaller than the third coefficient of thermal expansion of the main body. This is the case, for example, for aluminum as material for the main body.

In order to prevent unwanted reflections of light within the housing cap, the inside of the housing and hence in particular the inside of the housing cap may be in blackened form, especially in matt blackened form, for which it is possible to use a paint or a coating, for example black chrome-plating, a dark nickel coating or a zinc-nickel coating, in particular also as an electrolytic coating. In this way, it is possible for 98% or more of the light incident on a surface coated in this way to be absorbed in the wavelength range used by the electronic component accommodated. Dark nickel coatings may be formed, for example, by influencing the deposition parameters of the electrolytic coating such that a rough and dark-colored nickel layer is produced.

As already set out, the material of the compensation element is preferably chosen such that, because of the coefficient of thermal expansion thereof after the bonding of the window, compressive stress is exerted on the first bonding material. Examples of suitable materials for the compensation element include iron-nickel alloys, iron-nickel-cobalt alloys, ferritic stainless steel and titanium. Suitable examples of iron-nickel alloys especially include NiFe42 and NiFe46. A suitable example of a ferritic stainless steel is AISI 430.

The first bonding material is preferably a glass solder. Particular preference is given here to glass solders based on a lead-zinc glass or a bismuth-zinc glass. Likewise preferred are all glass solders having a processing temperature below 600° C. The processing temperature of a glass solder means the temperature at which the glass solder has a viscosity of 1·10⁴ dPa·s.

When a glass solder is used, the first bonding material is preferably chosen such that the coefficient of thermal expansion thereof is matched to the first coefficient of thermal expansion of the window such that there are no stresses between the window and the first bonding material after cooling after the production of the bond.

After the window and the compensation element have been bonded, a solder layer is formed between window and compensation element, and, in the case of use of a glass solder, preferably has a thickness in the range from 20 μm to 300 μm, more preferably in the range from 50μ to 100μ.

The second bonding material is preferably a metal solder. Depending on the sequence of assembly, i.e. whether the window is first bonded to the compensation element using a glass solder or the compensation element is first bonded to the main body using a metal solder, preference is given to using a hard solder or a soft solder. Preference is given to using a hard solder when the compensation element is to be secured to the main body before the glass soldering process, since the melting temperature of the hard solder is above a processing temperature of the glass solder. In the reverse case, preference is given to using a soft solder having a melting temperature below the transformation temperature of the glass solder. Particular preference is given here to hard solders such as CuAg, CuAgIn, CuAgPd and CuAgNi. In the case of use of a soft solder, SnAgCu is preferred.

After the compensation element and the main body have been bonded, a solder layer is formed between main body and compensation element, and, in the case of use of a metal solder, preferably has a thickness in the range from 10 μm to 200 μm, more preferably in the range from 20μ to 100μ.

The housing cap is preferably set up and configured such that it can be joined to further housing parts to form a housing. For this purpose, the main body of the housing cap preferably comprises a flange for bonding to a housing base.

The flange preferably takes the form of a circumferential flange adjoining the side walls of the main body. The flange is preferably in one-piece form together with the side walls of the main body. A width of the flange is, for example, in the range from 1 mm to 5 mm.

If the inside of the housing cap is blackened, a flange region of the main body is preferably unblackened. This prevents the surface treatment undertaken for the blackening from impairing bondability, especially solderability or weldability, of the flange surface.

The main body and the window are bonded to one another, preferably hermetically sealed, using the compensation element and the first and second bonding materials. A hermetic seal is considered in particular to mean an He leakage rate of 1.10-8 mbar l/s at a pressure difference of 1 bar.

The hermetically sealed bonding makes it possible to create a housing cap and hence a housing having a hermetically sealed interior. In this way, it is possible firstly to prevent the penetration of substances from the environment, for example moisture or aggressive chemicals. Secondly, it is also possible, however, to maintain protective atmospheres introduced into the interior of the housing. For example, an upper limit of 5000 ppm may be defined for water vapor within the housing. A method of measuring the water vapor trapped in a housing is specified, for example, as MIL-STD-883 Method 1018.

A further aspect of the invention relates to a housing for an electronic component that comprises one of the housing caps described herein and a housing base.

The housing base is preferably bonded to the main body of the housing cap by welding or soldering. The bond between the main body and the housing base is preferably hermetically tight.

The third coefficient of thermal expansion of the main body of the housing cap of the housing is preferably matched to a fourth coefficient of thermal expansion of the housing base. This achieves the effect that, in the event of temperature fluctuations, there is no occurrence of any unwanted deformation of the housing that could result, for example, in a change in alignment of the electronic component relative to the window.

The material of the housing base is preferably a ceramic, especially an Al₂O₃- or AlN-based ceramic, or a metal, especially an iron-nickel-cobalt alloy such as Kovar®.

If the material for the housing base is chosen to be a metal, this is preferably chosen to be identical with the material of the main body of the housing cap.

For accommodation of the electronic component in the housing, this may include further components, for example a pedestal. The pedestal is preferably secured on the housing base or executed in one-piece form therewith.

The electronic component may especially be an optoelectronic component such as a light-emitting diode (LED), a LASER, especially in the form of a laser diode, or a photodiode.

For electronic contact connection of the electronic component accommodated in the housing, the housing may have one or more electrical bushings. These are preferably disposed in the housing base. The electrical bushings may take the form, for example, of fixing material-metal bushings, in which a metallic conductor is held by means of a fixing material in an opening of the housing.

These fixing material-metal bushings are preferably executed in hermetically sealed form.

The proposed housing cap enables housings with small dimensions. In the case of an essentially cuboidal housing, the length and width may be chosen, for example, within the range from 10 mm to 100 mm, preferably within the range from 20 mm to 80 mm, more preferably within the range from 30 mm to 50 mm. The height of the housing may be chosen, for example, within the range from 2 mm to 40 mm, preferably within the range from 5 mm to 20 mm and more preferably within the range from 8 mm to 15 mm. A housing set up for accommodation of a laser diode has, for example, a length and width of 45 mm, with a height of 11 mm.

By arrangement of the window on the side of the housing, it is suitable in particular for accommodation of side-emitting laser diodes as optoelectronic component. The side-emitting laser diode may be applied here flatly, i.e. especially parallel, to a printed circuit board in the interior of the housing. There is thus no need for an assembly platform for the arrangement of the laser diode at an angle of 90°, which simplifies the construction of the housing.

For bonding of the window to the main body using the compensation element and the two bonding materials, the bonding materials or precursors containing the bonding materials are disposed between the compensation element and the window or the main body and then heated to a temperature above the melting point of the bonding material in question. The bonding material then wets the surfaces involved on the compensation element and the window or the main body. After subsequent cooling, a bonding layer is formed between the compensation element and the window or the main body which consists of the bonding material.

If the first bonding material and the second bonding material have different melting temperatures, the bonding can be effected in two separate steps. In this case, a bond is first made using the bonding material having the higher melting point and then, in a further step, a further bond is made using the bonding material having the lower melting point.

### EXAMPLE

A window having a thickness of 1.0 mm and made of sapphire, also referred to as sapphire glass, is to be bonded to a main body composed of an iron-nickel-cobalt alloy known by the Kovar® name. The coefficient of thermal expansion of the iron-nickel-cobalt alloy is about 5 ppm/K (5·10⁻⁶ K⁻¹) and hence is smaller than the coefficient of thermal expansion of sapphire, which, parallel to the C axis, is about 5.6 ppm/K. The first bonding material used is a lead oxide-zinc oxide glass solder, which, with a coefficient of thermal expansion of about 5.7 ppm/K, is matched to the coefficient of thermal expansion of sapphire. The compensation element used is a frame having a circumferential elevated edge. The thickness of the frame is 0.5 mm, and the circumferential edge is elevated by 1.0 mm compared to the rest of the frame. The material used for the compensation element is the nickel-iron alloy NiFe 46 with a nickel content of 46%, which uses a coefficient of thermal expansion of about 7.4 ppm/K. For bonding of the compensation element to the main body, eutectic CuAg is used as hard solder. In a first step, the frame is bonded to the main body using the hard solder at a solder temperature of about 780° C. In a subsequent second step, the window is bonded to the frame using the glass solder at a processing temperature of about 450° C.

In this example, the first coefficient of thermal expansion of the window is 5.6 ppm/K and is thus smaller than the second coefficient of thermal expansion of the compensation element of 7.4 ppm/K. The second coefficient of thermal expansion in this example is greater than the third coefficient of thermal expansion of the main body, which is 5 ppm/K here.

The housing cap thus obtained was subjected to a thermal cycling test by conducting 15 temperature cycles between a low temperature of −65° C. and an elevated temperature of 150° C. by dipping into a liquid at that temperature. This test method is known as MIL883 Method 1011 Condition C.

The bond obtained between the main body and the window is hermetically tight even after performance of the thermal cycling test. For this purpose, a helium leakage rate was determined, and “hermetically tight” is considered to mean an He leakage rate of less than 1.10-8 mbar l/s at a pressure difference of 1 bar.

The invention further relates to the use of one of the housing caps described herein or of one of the housings described herein in a multilaser arrangement, or in a LIDAR sensor.

In the case of multilaser arrangements, there are two or more lasers as electronic components disposed in the housing formed, the emission axes of which are aligned parallel to one another. The lasers may be disposed here, for example, on a common pedestal of the housing.

In the case of a LiDAR sensor, at least one laser and/or one photodiode as an electronic component is disposed in the housing. It may be the case here that further components, for example a scanning unit for controlled deflection of a laser beam and optionally a detector, are also disposed in the same housing.

The invention is to be described in more detail hereunder with reference to the figures and without restriction thereto.

The figures show:

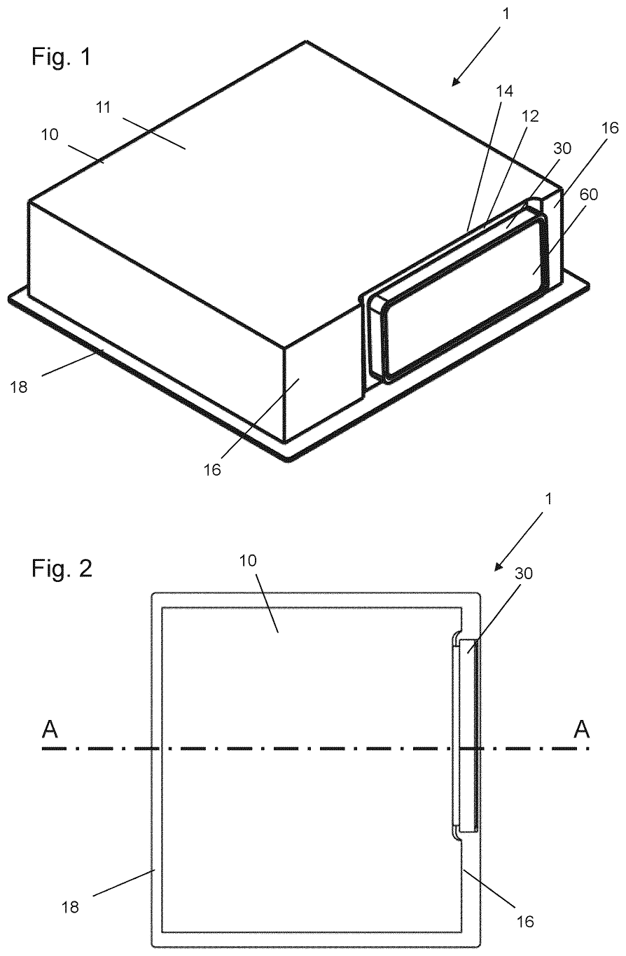

FIG. 1 shows a perspective diagram of a housing cap,

FIG. 2 shows the housing cap in a view from the top,

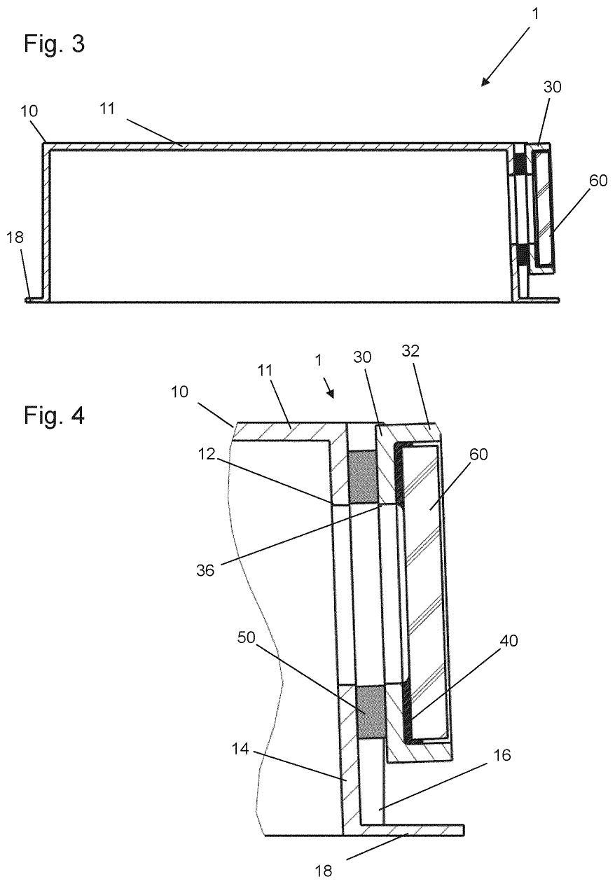

FIG. 3 shows a section through the housing cap along the section line marked in FIG. 2,

FIG. 4 shows an enlarged detail of the section view from FIG. 2,

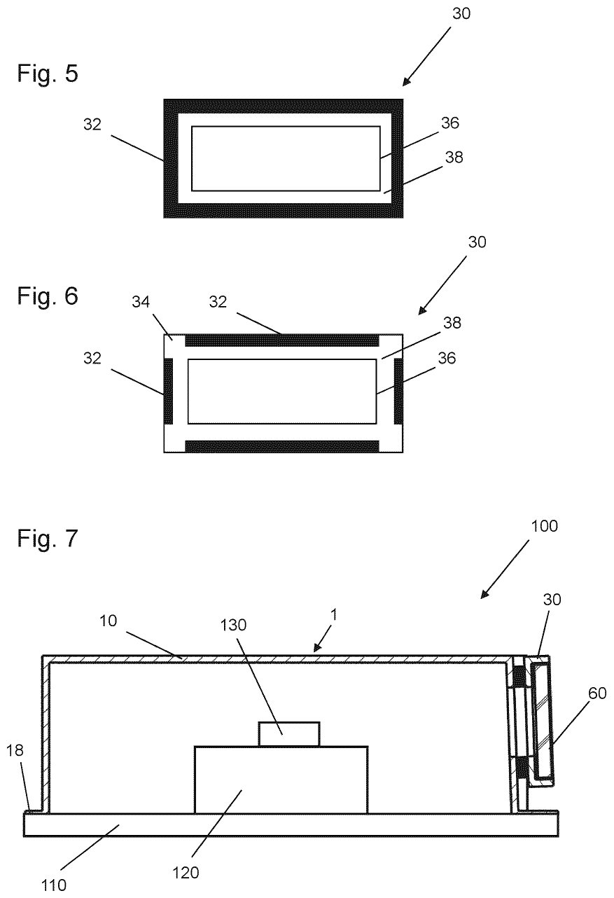

FIG. 5 shows a first variant of the compensation element,

FIG. 6 shows a second variant of the compensation element and

FIG. 7 shows a section through a housing with the housing cap and electronic component accommodated in the housing.

FIG. 1 is a perspective diagram of a housing cap 1. The housing cap 1 comprises a main body 10, preferably manufactured from a metal. The main body 10, in the example shown in FIG. 1, has a top wall 11 and four side walls 14. In one of the side walls 14, there is an opening 12 closed by a window 60. The window 60 is not bonded directly to the side wall 14 of the main body 10 here, but is secured on the main body 10 via a compensation element 30 in the form of a frame. In the example shown, the housing cap 1 has exactly one opening 12. In further embodiments, there may alternatively also be several openings 12, all of which are closed in the same way by a window 60. It is also conceivable that several openings 12 are collectively closed by a single window 60.

The compensation element 30 in the form of a frame has an elevated edge 32 that protrudes above the window 60 and hence provides protection of the window 60 from mechanical damage. Additional mechanical protection is achieved by protruding regions 16 of the side wall 14 that adjoin a region with the opening 12.

The housing cap 1 is set up, together with a housing base 110, to form a housing 100 for an electronic component 130; cf. FIG. 7. For this purpose, the housing cap 1, according to the working example shown in FIG. 1, has a bonding flange 18 suitable, for example, for soldering or welding of the housing cap 1 to a housing base 110.

FIG. 2 represents the housing cap 1 described with reference to FIG. 1 in a view from the top. In this view, it is readily apparent that the protruding regions 16 surround parts of the compensation element 30 in the form of a frame, but in this working example do not project beyond the window 60; cf. FIG. 1. However, the width of the bonding flange 18 is chosen such that it projects beyond the window 60 and hence additionally constitutes mechanical protection of the window 60 at least on the underside.

FIGS. 3 and 4 show a section view of the housing cap 1 described with reference to FIGS. 1 and 2 along the line marked A-A in FIG. 2. FIG. 4 shows a detail around the window 60 in an enlarged view.

In the section view, it is readily apparent that the window 60 is bonded to the main body 10 using the compensation element 30. The window 60 is cohesively bonded to the compensation element 30 via a first bonding material 40 here, for example in glass solder, and the compensation element 30 is in turn cohesively bonded to the main body 10 via a second bonding material 50, for example a metal solder.

The use of the compensation element 30 allows the material of the main body 10 to be chosen independently of the coefficient of thermal expansion of the window 60 and, at the same time, allows the transmission of tensile stresses to the window 60 and/or the first bonding material 40 to be avoided. For this purpose, the materials of the window 60 and of the compensation element 30 are chosen such that a first coefficient of thermal expansion of the window 60 is matched to a second coefficient of thermal expansion of the compensation element 30 or the first coefficient of thermal expansion is less than the second coefficient of thermal expansion. A third coefficient of thermal expansion of the main body 10 may then, in alternative i), be less than the second coefficient of thermal expansion of the compensation element 30. In other embodiments of the invention, in alternative ii), a material may also be selected for the main body 10 that has a third coefficient of thermal expansion very much greater than that of the compensation element 30. In these cases, the use of the compensation element 30 limits the compressive forces acting on a glass solder as first bonding material 40.

The compensation element 30 is configured in the form of a frame and, in the example shown in FIGS. 1 to 4, has an opening 36 that corresponds in size and shape to the opening 12 in the side wall 14 of the main body 10. In this example, the compensation element 30 in the form of a frame comprises an elevated circumferential edge 32, the height of which is chosen such that the elevated edge 32 protrudes beyond the window 60. As a result, the compensation element 30 additionally provides a protective effect from mechanical damage to the window 60. The elevated edge 32 additionally acts as a delimitation for the first bonding material 40. For the bonding of the window 60 to the compensation element 30, the first bonding material 40 is heated to a temperature above the melting point of the first bonding material 40, such that it is free-flowing and can establish the cohesive bond between window 60 and the compensation element 30. By virtue of the elevated edge 32, the first bonding material 40 cannot flow beyond the compensation element 30 here. Such outflow would be disadvantageous especially when this would establish direct contact between the first bonding material 40 and the main body 10. Differences in coefficients of expansion could in particular cause cracks in the first bonding material 40 that spread through the solder zone and could lead to a leak in the housing cap 1.

In the representation in FIGS. 3 and 4, it is additionally apparent that, in this example, the side wall 14 with the opening 12 is not arranged at right angles to the top wall 11 of the main body 10, but runs slightly obliquely thereto. As a result, the window 60 is also accommodated on the main body 10 in a position that differs from the 90° angle to the top wall 11, or to the housing base 110 or after joining to form a housing 100. This slightly oblique position of the window 60 can advantageously be utilized to avoid reflections of electromagnetic radiation. A laser beam emitted, for example, by a laser accommodated in the housing 100 formed is still partly reflected at the window 60 as before, but because of the oblique position does not go directly back into the laser source, such that faults in operation of the laser can be avoided. Alternatively, however, it is of course also possible to align the side wall 14 and hence the window 60 perpendicularly.

FIG. 5 shows a first working example of a compensation element 30. The compensation element 30 is configured in the form of a frame and has an opening 36 corresponding, for example, in shape and size to the opening 12 of the main body 10; cf. FIG. 4. Around the opening 36 is a contact surface 38 which is provided with the first bonding material 40 for connection to the window 60; cf. FIG. 4. The compensation element 30 shown in FIG. 5 has a circumferential elevated edge 32, the height of which, as shown in the example of FIGS. 1 to 4, may be chosen such that the elevated edge 32 projects above the window 60. The height of the elevated edge 32 may alternatively also be chosen differently, such that it does not project above the window 60 or concludes flush with the window 60.

FIG. 6 shows a second working example of a compensation element 30. The compensation element 30, as already described with reference to the first working example of FIG. 5, is configured in the form of a frame and comprises an elevated edge 32. A difference from the first working example is that the elevated edge here does not run around the full circumference, but is interrupted at the vertices 34 of the compensation element 30 in frame form. By virtue of this interrupted form of the circumferential edge 32, the compensation element 30 can easily be obtained from a flat metal sheet by bending.

FIG. 7 shows a schematic section diagram through a housing 100 comprising the housing cap 1 described with reference to FIGS. 1 to 4 and a housing base 110 joined to the housing cap 1.

The housing base 110 is cohesively bonded to the housing cap 1, for example by soldering or welding. The housing base 110, in the example shown, has a pedestal 120 bearing an electronic component 130. The electronic component 130 may, for example, be a laser diode arranged and aligned such that a laser beam emitted by the electronic component 130 runs parallel to the housing base 110 and the top wall 11 of the housing cap 1 and leaves the housing 100 through the window 60.

Although the present invention has been described with reference to preferred working examples, it is not limited thereto, but is modifiable in various ways.

### LIST OF REFERENCE NUMERALS

1 housing cap
10 main body
11 top wall
12 opening
14 side wall
16 protruding surface
18 flange
30 compensation element
32 elevated edge
34 vertex
36 opening
38 contact surface
40 first bonding material
50 second bonding material
60 window
100 housing
110 housing base
120 pedestal
130 electronic component

1. A housing cap for an electronic component, comprising a main body having an opening closed by a window, wherein the window is joined to the main body using a compensation element, wherein there is a cohesive bond using a first bonding material between the compensation element and the window and a cohesive bond using a second bonding material between the compensation element and the main body, wherein a first coefficient of thermal expansion of the window is matched to a second coefficient of thermal expansion of the compensation element or the first coefficient of thermal expansion is less than the second coefficient of thermal expansion.

2. The housing cap of claim 1, wherein i) the second coefficient of thermal expansion of the compensation element is greater than a third coefficient of thermal expansion of the main body or ii) the second coefficient of thermal expansion of the compensation element is less than the third coefficient of thermal expansion of the main body.

3. The housing cap of claim 2, wherein alternative i), the third coefficient of thermal expansion of the main body is at least 0.2 ppm/K, in alternative ii), the difference is at least 3 ppm/K.

4. The housing cap of claim 1, wherein the first bonding material is connected exclusively to the compensation element and the window.

5. The housing cap of claim 1, wherein the compensation element takes the form of a frame, and the shape of the frame optionally follows the shape of the opening of the main body.

6. The housing cap of claim 5, wherein the frame has an elevated edge to limit a flow of the first bonding material, wherein the elevated edge runs around the whole circumference or is interrupted at vertices of the frame.

7. The housing cap of claim 6, wherein the elevated edge protrudes above the window.

8. The housing cap of claim 1, wherein the opening is disposed in a side wall of the main body, and the side wall has surfaces projecting beyond the window that optionally protrude outside a region around the opening.

9. The housing cap of claim 1, wherein the material of the window is sapphire or is selected from a glass, especially a borosilicate glass or an optical glass such as BK7, a glass-ceramic, silicon or germanium.

10. The housing cap of claim 1, wherein the material of the main body is selected from a metal, selected from the group consisting of an iron-nickel-cobalt alloy, a stainless steel, aluminum, and molybdenum.

11. The housing cap of claim 1, wherein the material of the compensation element is selected from an iron-nickel alloy, an iron-nickel-cobalt alloy, a ferritic stainless steel and titanium.

12. The housing cap of claim 1, wherein the first bonding material is a glass solder, optionally based on a lead-zinc glass or a bismuth-zinc glass.

13. The housing cap of claim 1, wherein the second bonding material is a metal solder, or a hard solder.

14. The housing cap of claim 1, wherein the housing cap comprises a flange for bonding to a housing base.

15. A housing for an electronic component, comprising a housing cap of claim 1 and a housing base.

16. The housing of claim 15, wherein the third coefficient of thermal expansion of the main body of the housing cap of the housing is matched to a coefficient of thermal expansion of the housing base.

17. The housing as claimed in claim 15, wherein the material of the housing base is a ceramic.

18. (canceled)

19. The housing as claimed in claim 17, wherein the ceramic is Al₂O₃, AlN.

20. The housing as claimed in claim 17, wherein the metal is iron-nickel-cobalt alloy.
